(19) United States
(12) Patent Application Publication
(10) Pub. No.: US 2009/0102070 A1
(43) Pub. Date: Apr. 23, 2009

(54) Alignment Marks on the Edge of Wafers and Methods for Same

(75) Inventors: Claudius Feger, Poughkeepsie, NY (US); Nancy LaBianca, Yalesville, CT (US)

Correspondence Address: NUGENT & SMITH, LLP, 91 FOREST BOULEVARD, SUITE 100, ARDSLEY, NY, 10502, US

(73) Assignee: International Business Machines Corporation, Armonk, NY (US)

(21) Appl. No.: 11/876,677

(22) Filed: Oct. 22, 2007

(51) Int. Cl. H01L 23/544; H01L 21/78

(52) U.S. Cl. 257/797; 438/462; 257/E21.599; 257/E23.179

(57) ABSTRACT

A semiconductor wafer having alignment marks a sufficient distance from the outer wafer edge that reference dicing channels and a method for same. A process for dicing WLUF coated wafers into singulated chips using said alignment marks on the outer edge of the wafer.

### FIELD OF THE INVENTION

This invention relates to alignment marks on the edge of semiconductor wafers.

### BACKGROUND OF THE INVENTION

Flip chip technology is the fastest growing chip interconnect technology as it allows very large numbers of I/Os. Thus, the footprint of chips with low numbers of I/O's can be made very small. This is also true for associated packages such as chip-scale packages.

The major advantage of flip chip technology is that it can utilize the total chip area to make the I/O connections, while wire bonding uses only the chip periphery. A disadvantage of flip chip technology is that stresses that arise from the thermal mismatch between the silicon (chip) thermal expansion coefficient (CTE) and the CTE of the substrate are borne fully by the solder bumps used to make the interconnect between chip and substrate. In order to ameliorate said stresses flip chip packages are usually underfilled, i.e., a resin is placed between the chip and the substrate and acts as encapsulant of the solder bumps and an adhesive between chip and substrate. The effect of such underfills is that the long-time reliability of underfilled flip chip packages is greatly enhanced compared to not underfilled counterparts.

Such resin underfills can be applied by capillary flow, using a no-flow process or by wafer-level applied processes. There are several wafer-level applied underfill processes, among them the wafer-level underfill (WLUF) process which uses an over-bump wafer-applied resin, that is then b-staged, followed by dicing the wafer to singulate chips. The WLUF process has been described by Feger et al. (U.S. Pat. No. 6,919,420). FIG. 1 shows a prior art process through flow chart and actual depiction of the wafer surface, wherein the WLUF material is applied over the solder bumps. The wafer 10 has already been bumped and includes a multiple of solder bumps 20. The WLUF material 30 is applied over the solder bumps and is b-staged. The WLUF covers the solder bumps and depending on the thickness, may conceal the solder bumps and any other marks on the wafer surface

The WLUF resin material layer can obscure the dicing channels and other marks making it difficult to dice the wafers into chips. To dice the wafers into chips in the prior art process, the WLUF material either must be transparent or translucent, and the thickness of the layer must be thin enough so that the dicing channels are still visible. It is desirable to have a thicker WLUF material so that less air is trapped between the underfill and substrate, but a thicker WLUF material makes the dicing channels less visible. Thus, dicing a wafer into chips is a significant problem with a thicker WLUF material.

Accordingly, a need exists for semiconductor wafer having visible alignment marks while also having a thick WLUF material. The visible alignment marks can be used in dicing the wafer into chips. These and other needs are met by the inventive wafers and methods to provide alignment marks and alignment during wafer dicing of WLUF chips. Other advantages of the present invention will become apparent from the following description and appended claims.

### SUMMARY OF THE INVENTION

The invention is a semiconductor wafer having visible alignment marks on the edge of the wafer.

The invention is also a process for making visible said alignment marks on the edge of a wafer.

The invention is further a process for dicing a wafer into chips via alignment marks on the edge of the wafer.

Other embodiments of the invention are disclosed herein.

### BRIEF DESCRIPTION OF THE DRAWINGS

FIG. 1 is a flow chart and depiction of the prior-art over bump applied wafer level underfill process.

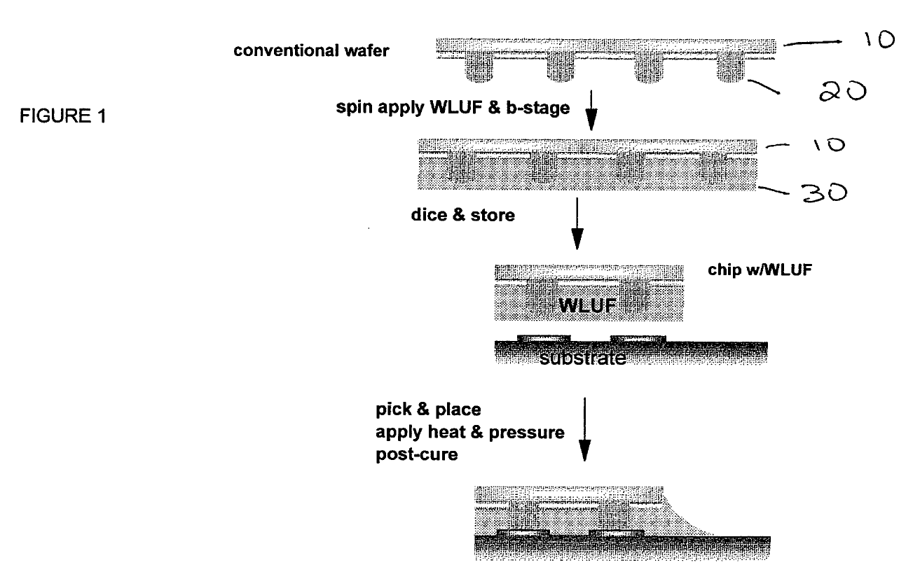

FIG. 2 is a picture showing a wafer with clearly defined dicing channels.

FIG. 3 is a schematic cross-section of the inventive wafer with alignment marks placed on a) the ILD structure and in another embodiment b) placed on the semiconductor wafer.

FIG. 4 is the schematic of conventional edge bead removal process.

FIG. 5 depicts a picture of the inventive wafer with visible alignment marks on the edge of the wafer after edge bead removal.

FIG. 6 is a schematic of the invention and the laser ablation process to visualize the alignment marks.

### DETAILED DESCRIPTION OF THE INVENTION

The invention is a semiconductor wafer having visible alignment marks on its edge and the process of dicing a WLUF coated wafer into singulated chips after making visible said alignment marks and using them to identify the dicing channels which are usually made invisible by the WLUF coating. The alignment marks are placed on the outer edge of the wafer allowing the alignment marks to reference dicing channels on the WLUF coated wafer.

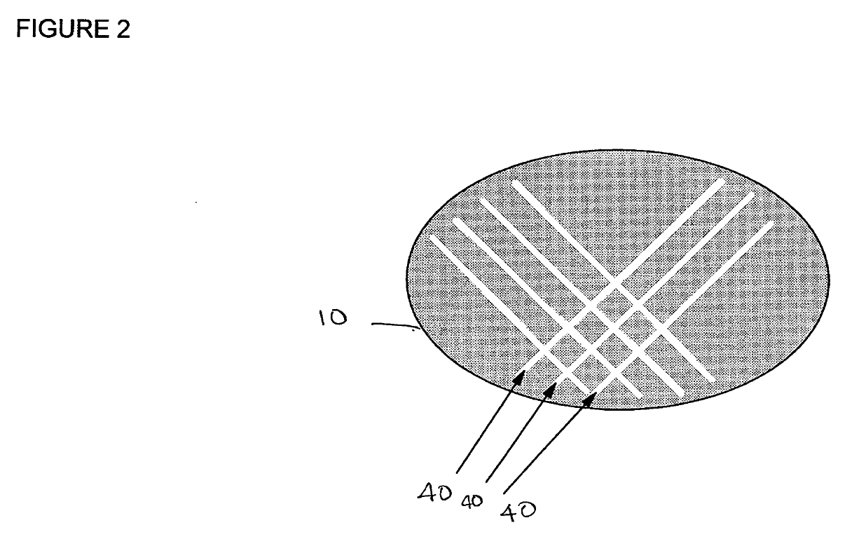

Any variety of WLUF coated wafers may be employed including but not limited to Si wafers or SiGe wafers. The WLUF process may be any known WLUF process, such as but not limited to that disclosed in U.S. Pat. No. 6,919,420. In the prior art process, the WLUF material must be either transparent or translucent enough in the layer thickness applied over dicing channels on the wafer, so that the dicing channel is fully or substantially visible. FIG. 2 shows a wafer 10 with clearly defined dicing channels 40. Visible dicing channels are necessary in order to dice the WLUF wafer into singulated chips. The conventional WLUF process can obscure all dicing marks or channels particularly if the WLUF material is opaque or if the WLUF layer is thick. In the prior art process, aligning a chip requires optically recognizing dicing channels and using this information to dice the WLUF wafer into chips, which is difficult, if the WLUF layer is thick.

The requirement of transparency or translucency of the WLUF material in the prior art in order to assist wafer dicing limits its range of filler content as well as its range of layer thickness. On the other hand, it has been found that thicker WLUF layers lead to less inclusion of air during chip to substrate joining and thus is desirable. These limitations are overcome with the current invention by alignment marks which are visibile along the edge of the wafer, via a variety of methods.

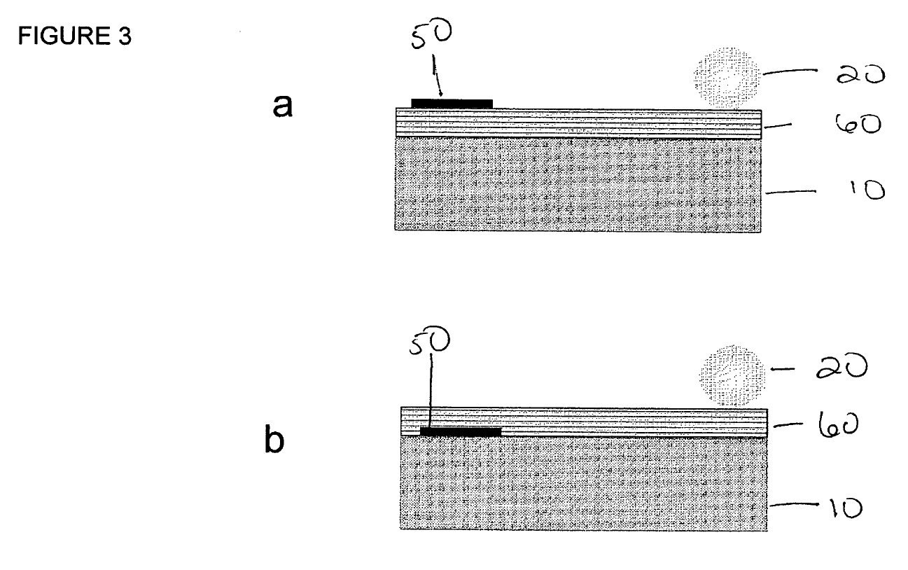

The inventive wafer includes alignment marks applied in the area of the outer edge of the wafer. Depending on the use of the wafer, the distance may vary. For example, where the alignment marks are placed on the top of the interlayer dielectric (ILD) structure during the far back-end-of-line (BEOL) process, they may be about 0.5 mm to about 5.0 mm from the outer edge of the wafer. The distance from the outer edge may even be redued to about 0.5 mm to about 2.0 mm from the edge of the wafer, but again this is dependent on the use of the wafer and the area being fabricated. Those of skill in the art will know the sufficient distance on the outer edge of the wafer to place the alignment marks so as to reference the location of the dicing channels. The alignment marks may be created either prior to the ILD structure being built or after the ILD structure is built. FIG. 3 shows the alignment marks 50 placed on the wafer 10 on a) the ILD structure 60 and in another embodiment b) the alignment marks 50 are placed on the semiconductor wafer under the ILD structure 60. If the alignment marks are to be deposited prior to the solder bump step, they may be created during the crack stop process, at the zero level, after the ILD layer deposition, or any combination thereof.

The alignment marks may be dicing marks created on the wafer when the chip design is produced in the wafer. Generally the dicing alignment marks are generated via a laser. The laser may be any known device such as those manufactured by Disco Corporation of Santa Clara, Calif. and/or Advanced Dicing Technologies of Horsham, Pa.

The alignment marks may consist of any variety of marks such as dots or strips of uniform or varying size referenced to one or more of the dicing channels on the wafer and placed on the outer edge of the wafer. The alignment marks may be geometric feature such as circles or squares or any shape. The alignment mark may also be a notch or any mark which can be used as a reference point. The alignment marks are placed in fixed relation to the dicing channels on the wafer such that with the knowledge of the location of these marks the position of the dicing channel location can be known exactly. If a wafer exhibits a notch or a flat face, as is often the case, one alignment mark would be sufficient₇ however, redundent alignment marks are preferred. The alignment marks may be placed such that an optical pattern recognition program can identify the alignment marks and deduct each mark's exact position with respect to the dicing channels on the wafer.

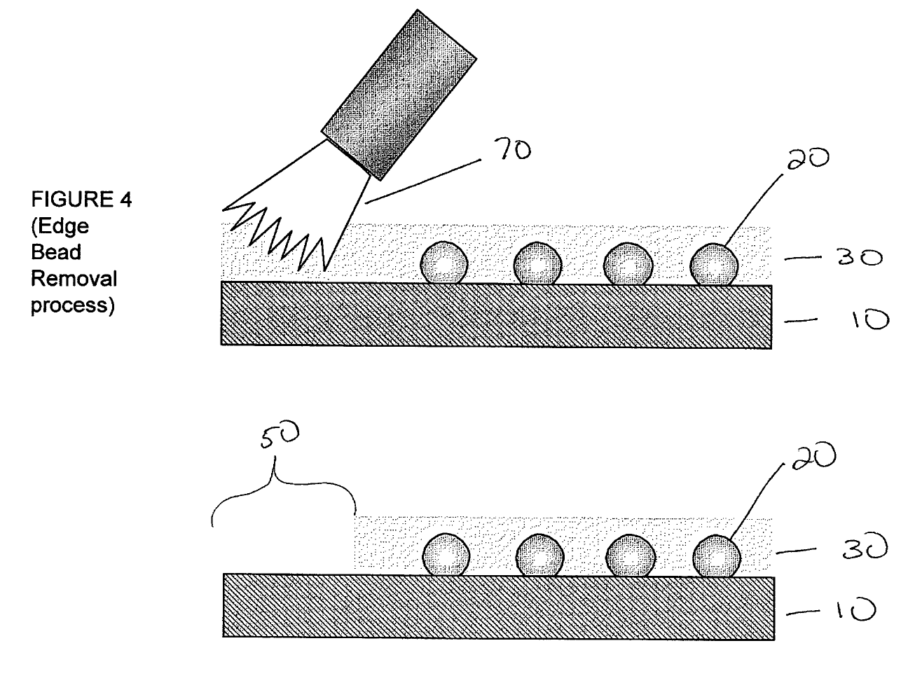

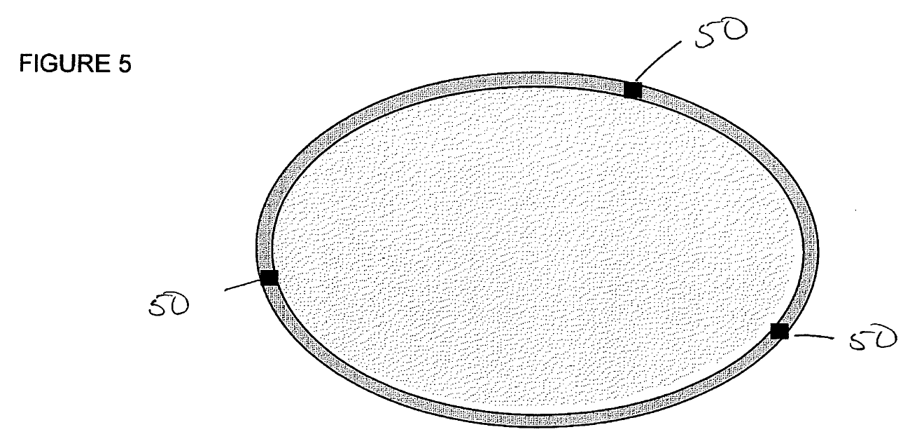

In one embodiment of the invention, the alignment marks are created after the formation of the ILD structure. Dicing marks are applied on the edge of the wafer on top of the ILD structure during the BEOL process. After subsequent processing including solder bumping and testing, the wafer is coated with the WLUF material. Edge bead removal techniques, such as but not limited to those disclosed in U.S. Pat. No. 4,732,785 or No. 6,565,920, are used to remove the edge bead. Thus alignment marks are made visible that were hidden under the edge bead. The edge bead may be removed by any known technique. For example, as shown in FIG. 4, in a conventional edge bead removal process which may be incorporated into spin-apply track tools, a stream of solvent 70 is directed onto the substrate edge while the substrate is spinning. The solvent stream dissolves and removes a portion of the spin-on film including the edge bead visibilizing the original surface. A mark may then be formed 50. Other edge bead removal processes as known to those skilled in the art can also be used. Even after b-staging of the WLUF material the alignment marks remain visible on the edge of the wafer. FIG. 5 shows an embodiment of the invention where the wafer 10 has three visible alignment marks 50 after edge bead removal and b-staging of the WLUF material 30.

The alignment marks on the exposed surface of the wafer edge are then used by the alignment methods common to those skilled in the art, such as used by various dicing tools to identify the alignment marks with great accuracy. For example, computer assisted automated pattern recognition may be used to dice the wafer based on reference to the alignment marks. The WLUF coated wafer is diced into singulated chips using the alignment marks to reference the dicing channels.

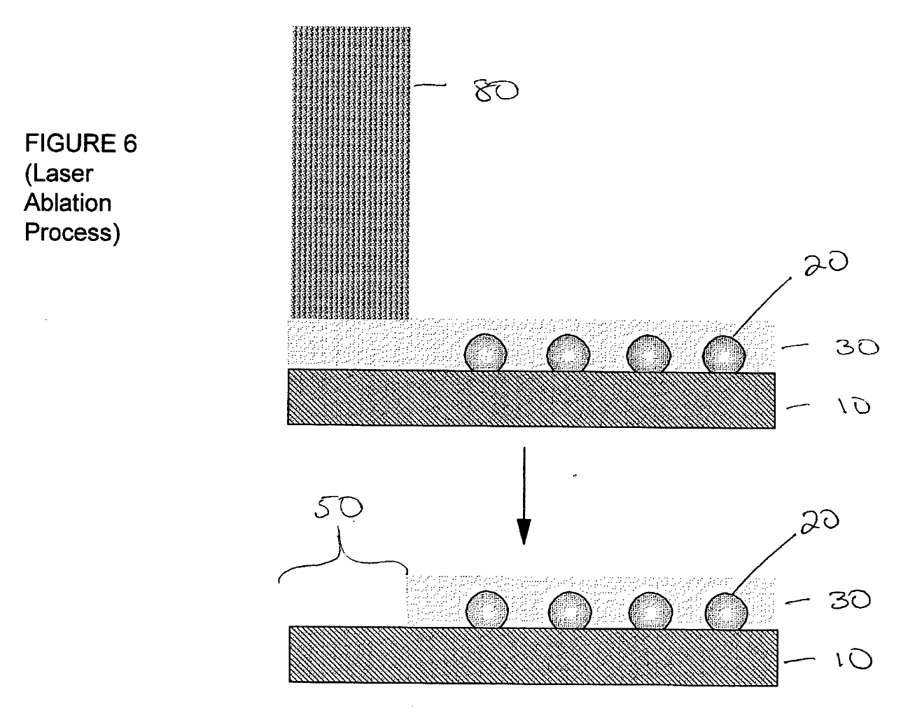

In a second embodiment of this invention the alignment marks are visualized via laser ablation of the WLUF material. Marks are applied on the edge of the wafer on top of the ILD structure. The WLUF material is deposited on the substrate via known methods. The WLUF material is then removed by a laser ablation method. The alignment marks are visible on the edge of the wafer. FIG. 6 shows the wafer 10 having solder bumps 20 and WLUF material 30 being laser ablated 80 to visualize the alignment marks 50.

In another embodiment of the invention, the alignment marks are created prior to application of the WLUF material. Marks are applied on the edge of the wafer on top of the ILD structure during the BEOL process. The WLUF material may then be deposited by screening through a stencil or mask. Any known method may be used such that the WLUF material does not coat the outer edge of the wafer. The stencil or mask is designed so that the marks located on the edge of the wafer remain uncoated by the WLUF material. The alignment marks on the outer edge of the wafer are uncoated by the WLUF materials and remain visible.

In a fourth final embodiment of this invention, the alignment marks are placed on the wafer before the ILD structure is built. The marks are applied to the edge of the wafer before the ILD structure is being built such as during the crack step process or at the zero level. After completion of the ILD structure, followed by solder bumping, testing, WLUF deposition and b-staging, a laser ablation process may be used to ablate both the WLUF material and ILD from the area on which the dicing marks are deposited. The alignment marks are made visible.

When the wafers having the alignment marks are ready for dicing, the alignment marks are used for the alignment of the wafer by methods common to state-of-the-art dicing tools to identify the dicing channels with great accuracy.

The process and structure of the present invention is further illustrated by the following non-limiting examples.

### EXAMPLE 1

Three alignment marks are applied to a silicon wafer during the far BEOL process, i.e. on top of the ILD structure. The three base alignment marks are located not equidistant on the periphery of the wafer. The wafer process is continued through solder bumping, testing, and application of a WLUF material. An edge bead removal process is applied and the alignment marks under the edge bead are made visible. The WLUF material is b-staged, and the alignment marks remain visible. The alignment marks are referenced to the dicing channels and thus identify the dicing channels with great accuracy. Using the dicing channels thus identified, the wafer is diced into separate chips.

### EXAMPLE 2

Three alignment marks are applied to a silicon wafer during the far BEOL process. The alignment marks are placed on the edge of the wafer on top of the ILD structure. The wafer process is continued through solder bumping, testing, and application of a WLUF material. The WLUF material is deposited by screening through a stencil such that alignment marks on the edge of the wafer remain uncoated by the WLUF material and remain visible. The WLUF material is b-staged and the alignment marks again remain visible. The alignment marks are referenced to the dicing channels and thus identify the dicing channels with great accuracy. Using the dicing channels thus identified the wafer is diced into separate chips.

### EXAMPLE 3

Three alignment marks are applied to a silicon wafer. The alignment marks are placed on the edge of the wafer on top of the ILD structure. The wafer process is continued through solder bumping, testing, WLUF material deposition and b-staging. The wafer is then ablated with a laser only on the outer edge to ablate the WLUF material and leave the ILD structure. The alignment marks are visible. The alignment marks are referenced to the dicing channels and thus identify the dicing channels with great accuracy. Using the dicing channels thus identified, the wafer is diced into separate chips.

### EXAMPLE 4

Three alignment marks are applied to the edge of a silicon wafer during the near BEOL process. The alignment marks are placed on the outer edge of the wafer below the ILD structure. The wafer process is continued through ILD build up, solder bumping, testing, and application of a WLUF material. The wafer is then ablated with a laser only on the edge to ablate both the WLUF material and the ILD structure. The alignment marks are visible. The alignment marks are referenced to the dicing channels and thus identify the dicing channels with great accuracy. Using the dicing channels thus identified, the wafer is diced into separate chips.

The invention has been described in terms of preferred embodiments thereof, but is more broadly applicable as will be understood by those skilled in the art. The scope of the invention is only limited by the following claims.

1. A semiconductor wafer comprising:
(a) at least two dicing channels on the wafer; and
(b) at least two visual alignment marks deposited on an outer edge of the wafer, wherein the alignment marks reference the location of the dicing channels.

2. The semiconductor wafer of claim 1 where the placement on the outer edge of the wafer is at a location sufficient to reference the dicing channels.

3. The semiconductor wafer of claim 1 wherein the alignment marks are at a distance of about 0.5 mm to about 5.0 mm from the wafer edge.

4. The semiconductor wafer of claim 1 wherein the alignment marks are at a distance of about 0.5 mm to about 2.0 mm from the wafer edge.

5. The semiconductor wafer of claim 1 where at least one mark is a notch cut in the periphery of the wafer.

6. The semiconductor wafer of claim 1 where at least one mark is a geometric feature cut in the periphery of the wafer.

7. The semiconductor wafer of claim 1 wherein the alignment marks are recognizable by automated pattern recognition.

8. The semiconductor wafer of claim 1 further comprising an interlayer dielectric connect structure.

9. The semiconductor wafer of claim 1 further comprising solder bumps.

10. The semiconductor wafer of claim 6 further comprising a wafer level underfill material layer over the solder bumps.

11. The semiconductor wafer of claim 10 wherein the alignment marks are made visible by an edge bead removal process of the wafer level underfill material layer.

12. The semiconductor wafer of claim 11 wherein the wafer level underfill material layer is b-staged.

13. The semiconductor wafer of claim 10 wherein the alignment marks are made visible through laser ablation of the wafer level underfill material layer before or after b-staging of the wafer level underfill material.

14. The semiconductor wafer of claim 13 wherein the interlayer dielectric connect structure is also laser ablated.

15. The semiconductor wafer of claim 10 wherein the wafer level underfill material layer is applied through a stencil which does not cover the outer edge of the wafer.

16. A process for dicing wafers into chips using the alignment marks of claim 1.

17. A process for producing alignment marks on the outer edge of a semiconductor wafer comprising;
a) depositing at least two alignment marks on a wafer having at least two dicing channels;
b) bumping the wafer such that solder bumps are created;
c) depositing a wafer level underfill material layer onto the wafer; and
d) removing a portion of the the wafer level underfill material layer along an outer edge region of the wafer to expose the alignment marks.

18. The process of claim 17 wherein the alignment marks are placed on the outer edge of the wafer at a location sufficient that the alignment marks reference the dicing channels.

19. The process of claim 17 wherein the wafer level underfill material is removed through an edge bead removal process.

20. The process of claim 17 wherein the the wafer level underfill material is removed through laser ablation.

21. The process of claim 17 wherein the alignment marks are at a distance of about 0.5 mm to about 5.0 mm from the wafer edge.

22. A process for dicing wafers into chips using the alignment marks of claim 17.

23. A process for producing alignment marks on the edge of a semiconductor wafer comprising:
a. depositing at least two alignment marks on an outer edge of a wafer having at least two dicing channels;
b. bumping the wafer such that solder bumps are created; and
c. depositing a wafer level underfill material layer onto the wafer through a stencil which does not cover the outer edges of the wafer

24. The process of claim 23 wherein the alignment marks are placed on the outer edge of the wafer at a location sufficient that the alignment marks reference the dicing channels.

25. The process of claim 23 wherein the alignment marks are at a distance of about 0.5 mm to about 5.0 mm from the wafer edge.

26. A process for dicing wafers into chips using the alignment marks of claim 23.

27. A process for producing alignment marks on the edge of a semiconductor wafer comprising:
a. depositing at least two alignment marks on an outer edge of a wafer;
b. creating an interlayer dielectric connect structure;
c. bumping the wafer such that solder bumps are created;
d. depositing a wafer level underfill material layer over the solder bumps;
e. b-staging the wafer level underfill material; and
f. laser ablating the wafer level underfill material on the outer edge of the wafer to expose the alignment marks.

28. The process of claim 27 wherein the alignment marks are placed on the outer edge of the wafer at a location sufficient that the alignment marks reference the dicing channels.

29. The process of claim 27 wherein the alignment marks are at a distance of about 0.5 mm to about 5.0 mm from the wafer edge.

30. A process for dicing wafers into chips using the alignment marks of claim 27.

31. A process for producing alignment marks on the edge of a semiconductor wafer comprising:
a. creating an interlayer dielectric connect structure through a back-end-of-line process;
b. depositing at least two alignment marks on an outer edge of a wafer
c. bumping the wafer such that solder bumps are created;
d. depositing a wafer level underfill material layer over the solder bumps;
e. b-staging the wafer lever underfill material; and
f. laser ablating the wafer level underfill material and the interlayer dielectric on the outer edge of the wafer to expose the alignment marks.

32. The process of claim 31 wherein the alignment marks are placed on the outer edge of the wafer at a location sufficient that the alignment marks reference the dicing channels.

33. The process of claim 31 wherein the alignment marks are at a distance of about 0.5 mm to about 5.0 mm from the wafer edge.

34. A process for dicing wafers into chips using the alignment marks of claim 1.

35. A semiconductor wafer comprising:
(a) at least two dicing channels on the wafer;
(b) at least two visual alignment marks deposited on an outer edge of the wafer, wherein the alignment marks reference the location of the dicing channels;
(c) an interlayer dielectric connect structure;
(d) solder bumps; and
(e) a wafer level under-fill material layer over the solder bumps.

36. The semiconductor wafer of claim 35 wherein the alignment marks are at a distance of about 0.5 mm to about 5.0 mm from the wafer edge.

37. A semiconductor wafer comprising:
(a) an interlayer dielectric connect structure via a back-end-of-line process;
(b) atleast two alignment marks on an outer edge of a wafer, wherein the alignment marks reference the location of the dicing channels;
(c) solder bumps; and
(d) a b-staged wafer level underfill material layer over the solder bumps;
wherein the at least two alignment marks are visible via laser ablation of the b-staged wafer level underfill layer.

38. The semiconductor wafer of claim 37 wherein the alignment marks are at a distance of about 0.5 mm to about 5.0 mm from the wafer edge.
